(19) United States
(12) Patent Application Publication
(10) Pub. No.: US 2015/0107654 A1
(43) Pub. Date: Apr. 23, 2015

(54) SOLAR CELL AND PROCESS FOR MANUFACTURING A SOLAR CELL

(71) Applicant: SolarWorld Innovations GmbH, Freiberg (DE)

(72) Inventors: Franziska Wolny, Dresden (DE); Gerd Fischer, Borthen (DE); Torsten Weber, Dresden (DE)

(21) Appl. No.: 14/504,462

(22) Filed: Oct. 2, 2014

(30) Foreign Application Priority Data
Oct. 23, 2013 (DE) 102013111680.9

(51) Int. Cl. H01L 31/0216; H01L 31/18; H01L 31/048

(52) U.S. Cl. CPC H01L 31/02167; H01L 31/0481; H01L 31/18
USPC 136/251; 136/252; 136/244; 438/57

(57) ABSTRACT

A solar cell includes a first dielectric layer on the shaded side of the solar cell; and a second dielectric layer on the first dielectric layer. The second dielectric layer includes Hydrogen and the Hydrogen content in the second dielectric layer is measured such that a refractive index of less than 2.0 results for the second dielectric layer.

### CROSS-REFERENCE TO RELATED APPLICATION

This application claims priority to German Patent Application Serial No. 10 2013 111 680.9, which was filed Oct. 23, 2013, and is incorporated herein by reference in its entirety.

### TECHNICAL FIELD

A solar cell and a process for manufacturing a solar cell are provided in different embodiments.

### BACKGROUND

In order to reduce the recombination losses on the rear side contact of a solar cell, in addition to the emitter, the rear side can also be passivated, e.g. in the form of a PERC-solar cell (passivated emitter and rear cell). PERC solar cells based on p-type Silicon, which contains Boron and Oxygen, lose 0% to >10% of their performance with reference to their initial (relative) performance by illumination as per Boron- and oxygen content. This decrease in performance is referred to as light induced degradation (light induced degradation—LID). For avoiding the light induced degradation, normally preferred high ohmic Silicon wafers are employed, which contain lesser Boron. In addition, it is attempted to reduce the Oxygen content of the base material. However, certain electrical properties of the solar cell, for example the series resistance cannot be sufficiently optimized by means of the application of the high ohmic Silicon.

On the other hand, the decrease in performance can be permanently deactivated by LID in an additional process step at the end of the solar cell manufacture by high temperature under exposure to light, as described in the article “Investigations on the Long Time Behaviour of the Metastable Boron-Oxygen Complex in Crystalline Silicon”, Progress in Photovoltaic: Research Application, 2008; 16: 135-140 by A. Herguth, G. Schubert, M. Kaes and G. Hahn;; and in the article “Light induced degradation and regeneration of high efficiency Cz PERC cells with varying base resistivity” by F. Wolny, T. Weber, M. Müller, G. Fischer, in Energy Procedia 38 (2013) 523-530. These permanent deactivation is also referred to as Regeneration.

### SUMMARY

A solar cell includes a first dielectric layer on the shaded side of the solar cell; and a second dielectric layer on the first dielectric layer. The second dielectric layer includes Hydrogen and the Hydrogen content in the second dielectric layer is measured such that a refractive index of less than 2.0 results for the second dielectric layer.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a schematic cross-sectional view of a solar cell according to different exemplary embodiments;

FIGS. 2A and 2B show the representations in connection with the changes of the time curve of the regeneration by variation of the SiN refractive index;

FIG. 3 shows a representation of the time curve of the light induced degradation of solar cells in cells and module; and

FIG. 4 shows a diagram of the process for manufacturing a solar cell.

### DESCRIPTION

In the following detailed description, a reference is made to the accompanying drawings forming part of this and in which specific embodiments are shown for illustration, in which the invention can be exercised. In this context, the directional terminology such as, “above”, “below”, “in front”, behind/rear”, “forward”, “rearward”, etc. are used with reference to the orientation of the described figure(s). Since components of the embodiments can be positioned in a number of different orientations, the directional terminology is used for illustration and is not limited in any way. It is obvious that other embodiments can be used and structural or logical changes can be made without departing from the scope of protection of the present invention. It is obvious that the features of the different exemplary embodiments described herein can be combined with each other, unless otherwise specified. Therefore, the following detailed description is not to be understood in a restrictive sense, and the scope of protection of the present invention is defined by the accompanying claims.

In the context of this description, the terms “connected”, “attached” and “coupled” are used for describing a direct as well as an indirect connection, a direct or indirect attachment and a direct or indirect coupling. Identical or similar elements are provided with identical reference numerals in the figures, where appropriate.

A solar cell and a process for manufacturing a solar cell are provided in different embodiments, by which the light induced permanent deactivation of the light induced degradation is possible in solar modules, for example solar modules which are based on PERC-solar cells, without enabling and amplifying the additional process step.

A solar cell is provided in different embodiments. The solar cell can have: a first dielectric layer on the shaded side of the solar cell; and a second dielectric layer on the first dielectric layer; wherein the second dielectric layer includes Hydrogen and the Hydrogen content in the second dielectric layer is measured such that a refractive index of less than 2.0 results for the second dielectric layer.

Obviously, the base material of the solar cell is not changed, but subsequently acts on the light induced degradation in the construction of the solar cell, i.e. in the cell process.

In one configuration, the second dielectric layer can include Silicon nitride with a layer thickness in a range of approximately 50 nm to approximately 200 nm, for example in a range of approximately 100 nm to approximately 150 nm.

In another configuration, the solar cell can be constructed as a PERC-solar cell (passivated emitter and rear cell—PERC).

In one configuration, a solar module can include a number of the above described solar cells. The solar cells can be electrically interconnected, for example in series and/or in parallel within a solar module.

In another configuration, the solar cells module can further include an encapsulation, wherein the encapsulation is configured such that the Hydrogen is embedded within the solar cell.

In another configuration, the encapsulation can include Ethyl vinyl acetate (EVA).

A process for manufacturing a solar cell is provided in different embodiments. The process can include: deposition of a first dielectric layer on a shaded side of the solar cell by addition of the gases Silane and Nitrogen dioxide (N20); subsequently depositing a second dielectric layer on the first dielectric layer by addition of the gases Silane and Ammonia, wherein the volume flow rate of the Ammonia is at least 10-folds greater than the volume flow rate of Silane, for example 15-folds greater than the volume flow rate of Silane.

In one configuration of the process, the second dielectric layer can be deposited as a Silicon nitride layer with a layer thickness in a range of approximately 50 nm to approximately 200 nm, for example in a range of approximately 100 nm to approximately 150 nm.

In another configuration, the solar cell can be constructed as a PERC-solar cell.

In another configuration, the process can further include heating the first dielectric layer and/or the second dielectric layer at approximately 500° C. to approximately 1000° C., for example, at approximately 600° C. to approximately 900° C., for example at approximately 700° C. to approximately 800° C. for a time period of approximately 1 sec to approximately 10 sec.

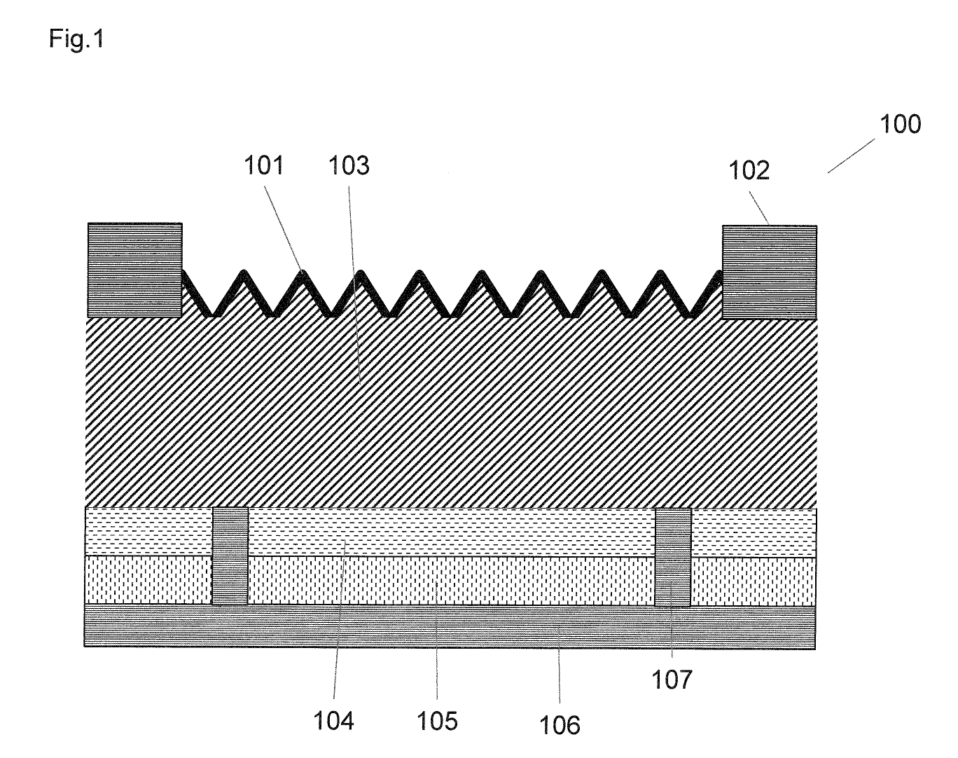

FIG. 1 shows a schematic cross-sectional view of a solar cell according to different exemplary embodiments.

The solar cell 100 can be a Silicon solar cell 100, for example a crystalline Silicon solar cell 100.

The solar cell 100 can be or are configured in the form of one of the following constructions: passivated emitter and rear side solar cell (passivated emitter and rear cell—PERC); and/or locally diffused, passivated rear side solar cell (passivated rear locally diffused cell—PERL).

In different exemplary embodiments, the solar cell 100 can have a first electrode 102, a second electrode 106 and an optically active region 103 between the first electrode 102 and the second electrode 106.

The first electrode 102 can be configured directly on the optically active region 103, i.e. on the light facing front side 101. The first electrode 102 can be configured, for example, as front side contact or front side metallization. The front side contact can be configured structured over the optically active region 103, for example, finger-shaped as metallization or in the form of a selective emitter or as a combination of both. A structured configured front side metallization can be configured, for example, essentially (except for electrical cross-linking) only on the optically active region 103.

The optically active region 103 of the solar cell has an electrically conducting and/or semiconducting material, for example—a doped Silicon, for example—p-doped (p-type), for example—with doping of Boron, Gallium and/or Indium; or n-doped (n-type), for example—with doping of Phosphorus, Arsenic and/or Antimony.

The optically active region 103 can absorb electromagnetic radiation and generates a photoelectric current therefrom. The electromagnetic radiation can have a wavelength range, which has X-rays, UV-radiation (A to C), visible light and/or Infrared-radiation (A to C).

The optically active region 103 has a first region, which is doped with a different dopant than a second region and remains in body contact with this. For example, the first region can be doped with a p-type (with p-dopant(s)) and the second region can be doped with an n-type (with n-dopant(s)), and vice-versa. A pn-junction is configured on the interface of the first region with the second region, on which electrons-hole pairs can be generated. The optically active region 103 can have several pn-junctions, for example next to each other and/or one above the other.

A rear side contact structure is configured on the shaded side of the solar cell 100. The rear side contact structure can have the second electrode 106 and a dielectric layer structure. The dielectric layer structure can have one or more dielectric layers between the contact openings 107 to the second electrode 106.

In an exemplary embodiment, the dielectric layer structure can have a first dielectric layer 104, wherein the first dielectric layer 104 is configured, disposed or deposited on or over the optically active region 103.

Furthermore, the dielectric layer structure can have a second dielectric layer 105. The second dielectric layer 105 can be configured, disposed or deposited on or over the first dielectric layer 104.

The first dielectric layer 104 can have, for example the same material as the second dielectric layer 105 or can be formed therefrom. The first dielectric layer 104 can have, for example—Silicon nitride (SiN), Silicon oxide (SiOx) and/or Silicon oxynitride (SiON). The first dielectric layer 104 can have, for example—a lower refractive index than the second dielectric layer 105.

For example, the first dielectric layer 104 can have a layer thickness in a range of approximately 10 nm to approximately 50 nm, for example—in a range of approximately 20 nm to approximately 50 nm.

The second dielectric layer 105 can be configured such that the refractive index of the second dielectric layer 105 lowers with increasing Hydrogen content in the second dielectric layer 105.

The Hydrogen can be chemically and/or physically bonded in the second dielectric layer 105, for example—bonded in the form of a doping of the second dielectric layer 105 and/or elements or molecules in cavities of the second dielectric layer 105.

For example, the Hydrogen content in the second dielectric layer 105 can be measured such that in a wavelength of 633 nm, a refractive index of less than 2.0 results for the second dielectric layer 105.

In an exemplary embodiment, the second dielectric layer 105 can have Silicon nitride, for example—a Hydrogen doped Silicon nitride (SiNx:H) or can be formed therefrom.

In an exemplary embodiment, the first dielectric layer 104 can have lower Hydrogen content than the second dielectric layer 105.

The second dielectric layer can have a layer thickness, which is in a range of approximately 50 nm to approximately 200 nm, for example—in a range of approximately 100 nm to approximately 150 nm.

Furthermore, the rear side contact structure of the solar cell 100 can have a second electrode 106, for example—in the form of a rear side metallization. The second electrode 106 can be used for tapping the light induced charge carriers, which are drained from the contact openings 107 out of the optically active region 103. In other words: the dielectric layer structure can have one or more electrically conductive regions, which are arranged for an electrical connection of the optically active region, for example—as interlayer contacts or interconnections. The interlayer contacts 107 can be configured as electrically conductive regions in the first dielectric layer 104 and the second dielectric layer 105 such that a continuous electrically conducting connection is configured through the dielectric layers 104, 105 and thus obviously through the entire dielectric layer structure.

The interlayer contacts 107 can have, for example—the same material as the second electrode 106 or can be configured therefrom, for example—a noble metal, semi-precious metal, Graphene, Graphite and/or carbon nanotubes.

Furthermore, a solar cell module can have one or more of the described solar cell 100. The solar cell module can have an encapsulation, which is configured such that the Hydrogen is embedded in the solar cell 100, for example—bonded. The encapsulation structure can have, for example—Ethylene vinyl acetate (EVA) or can be formed therefrom, for example—in the form of a film, a foil or a coating.

In case of an encapsulation with encapsulation structure, this can be configured, for example—such that the encapsulation structure has a refractive index, which approximately corresponds to the same refractive index of one of the respective layers adjoining the encapsulation structure.

The encapsulation can embed the Hydrogen contained in the solar cell 100 and can be used for a temperature distribution necessary for the permanent deactivation of the light induced degradation.

In different exemplary embodiments, a solar cell module can be configured with a number of the above described solar cells 100, wherein the number of solar cell are electrically connected in series and/or in parallel.

In a configuration, the second electrode 106 can be configured as a mirror for electromagnetic radiation.

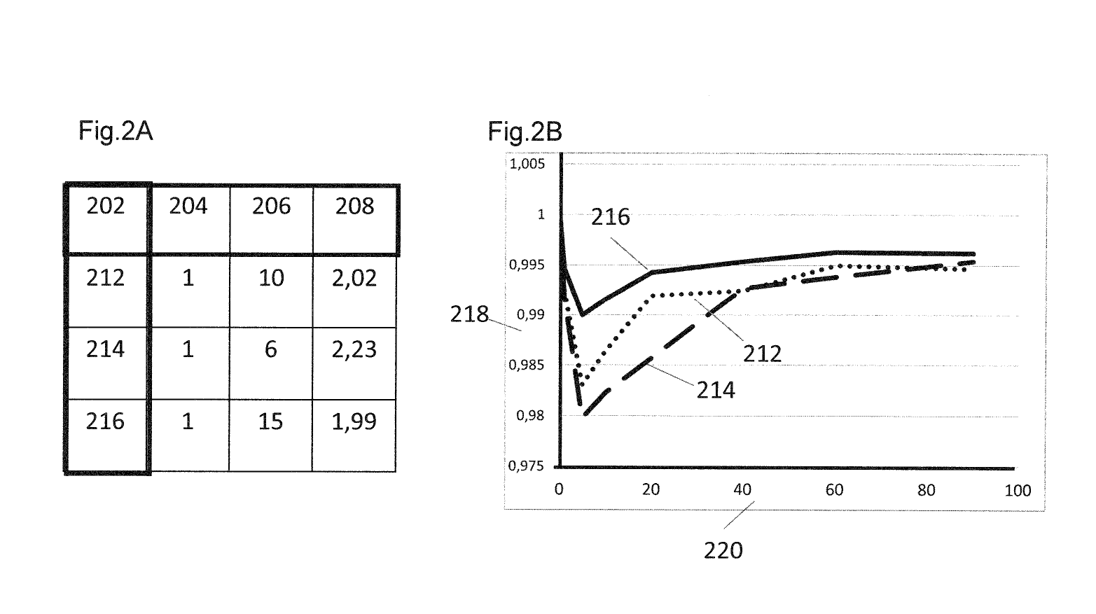

In FIG. 2A, the differences in the regeneration characteristics by an illumination at elevated temperatures caused by various compositions of the first dielectric layer and the second dielectric layer is illustrated according to different exemplary embodiments.

It is evident from FIG. 2A and FIG. 2B that the permanent deactivation of the light induced degeneration occurs faster, if the refractive index is adjusted under 2.0 for the SiNx:H layer by an appropriate SiH4:NH3 ratio in the deposition process, for example—in the CVD-Process. Thus, a second dielectric layer (for example—the second dielectric layer 105) is configured, which can be released and/or passed through more Hydrogen in the volume of the solar cell during the deposition and/or in the subsequent process steps.

FIG. 2A shows a table with 3 different process parameters (groups 212, 214 and 216) to the deposition of the layer structure with first dielectric layer 104 and second dielectric layer 105 from the above described space of parameters with two dielectric layers 104, 105 of/with SiNxH having respectively indicated refractive index 208. Furthermore, the ratios of the volume flow rates of silane 204 to ammonia 206 are indicated; standardized to the volume flow rate of silane.

In FIG. 2B is the efficiency in terms of the initial efficiency, i.e. the relative efficiency 218 as the average of three solar cells as a function of the exposure time 220 (in minutes) at a temperature of 165° C. for the solar cells of the group 212, 214 and 216 demonstrated from the table of the FIG. 2A, starting from solar cells directly after the manufacture. The exposure to light points to an approximate irradiance of 500 W/m2.

It is evident from FIG. 2A and FIG. 2B that the regeneration takes place faster, if an appropriate ratio of SiH4:NH3 is adjusted for the SiNx:H in the CVD process and a refractive index is adjusted below 2.0 for the SiNxH containing second dielectric layer (in FIG. 2B—216). For example, the solar cells 214 has a lower ratio of the volume flow rates (SiNx:H; 204:206), a higher refractive index 208 (see FIG. 2A) and a greater relative change in efficiency 214 (see FIG. 2B) than the solar cells with higher ratio of the volume flow rates (SiNx:H; 204:206, FIG. 2A).

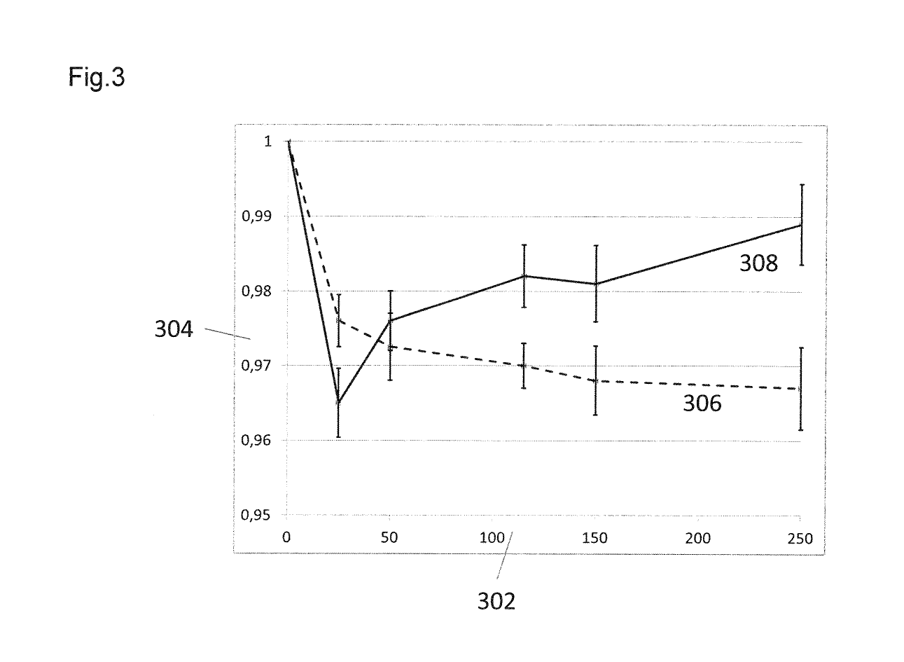

The difference of the light induced degradation (LID) of a solar cell and a solar cell module (Cz PERC here) according to different exemplary embodiments is illustrated in FIG. 3. The efficiency is illustrated in FIG. 3 with reference to the initial efficiency, i.e. the relative change in efficiency 304 as a function of the exposure time 302 at 50° C. for a group of 10 solar cells 306 (the average of 10 solar cells) and 10 single cell modules 308 (the average of 10 single cell modules). The positive influence of the lamination on the regeneration at standard degradation conditions is quite obvious. The represented error bars correspond to the standard deviation of the values of 10 solar cells or 10 single cell modules.

The refractive index of the second dielectric layer can be influenced by the Hydrogen content in the SiN layer.

It is obvious that in solar cells and solar cell modules (FIG. 3), the encapsulated solar cells do not degrade at the same conditions and do not recover, while the same solar cells initially degrade in a composite solar cell module, however this degradation is permanently deactivated with further irradiation. This considerably reduces the loss of power in a solar cell module by light induced degradation.

This behaviour is achieved by means of the above described targeted introduction of Hydrogen in the solar cell volume, for example—in a PERC cell process, the subsequent encapsulation of the solar cells in a suitable embedding material, which encloses the Hydrogen contained in the solar cells and is used for a temperature distribution necessary for the permanent deactivation of the light induced degradation.

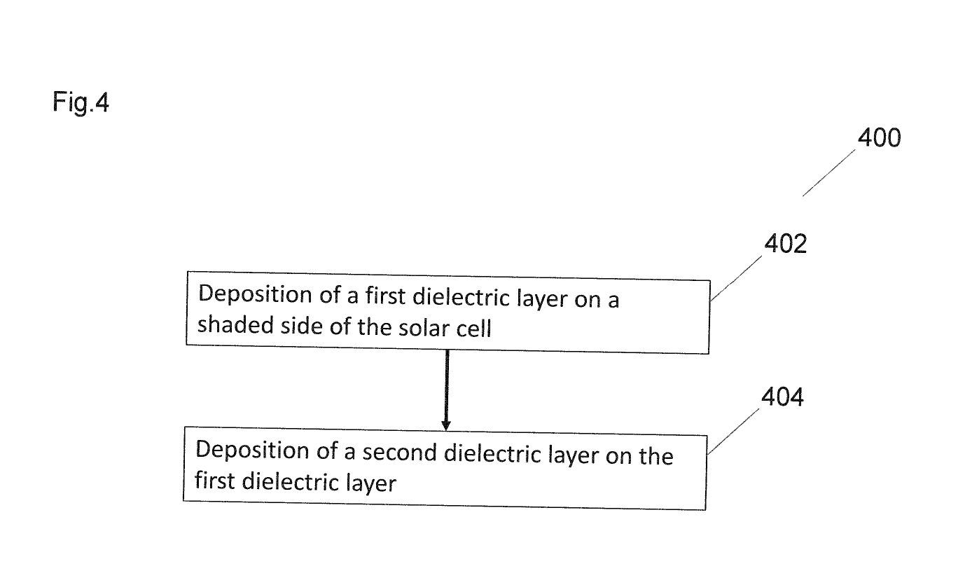

FIG. 4 shows a diagram for the process of manufacturing a solar cell 100. In different embodiments, the process 400 for manufacturing a solar cell 100 can have a deposition 402 of a first dielectric layer on a shaded side of the solar cell 100. During the deposition of the first dielectric layer, a predetermined gas or gas mixture, for example—a first gas and a second gas can be added. For example, the deposition can take place by addition of silane gas (as the first gas) and nitrogen dioxide (N20) (as the second gas). Therefore, the deposition takes place, for example—in a gas mixture of first gas and second gas, i.e. both gases are simultaneously present during the deposition of the first dielectric layer. The deposition of the first dielectric layer in the gas or gas mixture can take place in a gas stream or in an essentially static gas atmosphere. A static gas mixture can be meant by the volume streams as volume fractions and/or partial pressures, for example—physical gas depositions and/or physical deposition processes, for example—a cathode sputtering (sputtering).

Furthermore, the process includes the deposition 404 of a second dielectric layer on the first dielectric layer after the deposition of the first layer. During the deposition of the second dielectric layer, a predetermined gas or gas mixture, for example—a third gas and a fourth gas can be added. For example, the deposition can take place by adding the silane gas (as the third gas) and ammonia (as the fourth gas). The deposition of the second dielectric layer in the gas or gas mixture can take place in a gas stream or in a static gas atmosphere.

The targeted introduction of Hydrogen in the solar cell volume in the PERC-cell process can be configured by means of a variation of the Hydrogen content and/or by an optimization of the different dielectric layers in terms of their permeability for Hydrogen. The optimization of the permeability of the layers in terms of Hydrogen, for example—at the rear side contact structure with dielectric layers 104, 105 and electrode 106 can take place by means of an adjustment of the gas streams in a chemical gas phase deposition (chemical vapor deposition—CVD) of the rear side contact structure.

In one configuration, the volume flow rate of ammonia (NH₃) can be greater than or equal to approximately 6.8 slm; and the volume flow rate of silane (SiH₄) can be smaller than or equal to approximately 0.68 slm. For example, the volume flow rate of NH₃ can be greater than or equal to 7 slm and the volume flow rate of SiH₄ can be smaller than or equal to 0.5 slm. Thus, the volume flow rate of NH3 to the volume flow rate of SiH₄ can have a ratio, which is greater than or equal to 10:1, for example—greater than or equal to 15:1.

During deposition of the second dielectric layer, the volume flow rate of ammonia should be greater than the volume flow rate of silane, for example—at least 10 fold greater, for example—at least 15 fold greater.

During the deposition of the second dielectric layer, the gas or gas mixture can have one or more gases during the deposition of the first layer. Furthermore, more gases, for example—an inert gas, for example—nitrogen or a noble gas can be added during the deposition of the first dielectric layer and/or the second dielectric layer.

The second dielectric layer can be deposited as a Silicon nitride layer with high Hydrogen content.

The second dielectric layer can be deposited with a layer thickness in a range of approximately 50 nm to approximately 200 nm, for example—in a range of approximately 100 nm to approximately 150 nm.

Furthermore, the process 400 can include the heating of the first dielectric layer and/or the second dielectric layer at approximately 500° C. to approximately 1000° C., for example—at approximately 600° C. to approximately 900° C., for example—at approximately 700° C. to approximately 800° C. for a time period of approximately 1 sec to approximately 10 sec. Obviously, the adjustment of the Hydrogen permeability takes place by means of an adjustment of the subsequent high temperature step after the deposition, for example—in the PERC-cell process in order to ensure the diffusion of Hydrogen in the volume (bulk) of the solar cell.

In different embodiments, a solar cell and a process for manufacturing a solar cell are provided, by which it is possible to amplify the light induced permanent deactivation of the light induced degeneration in solar modules based on PERC-solar cells.

PERC-solar cells 100 are embedded in a solar module such that a permanent deactivation (also termed as regeneration) diminishes or compensates the occurring light induced degradation.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A solar cell, comprising:
a first dielectric layer on the shaded side of the solar cell; and
a second dielectric layer on the first dielectric layer;
wherein the second dielectric layer includes Hydrogen and the Hydrogen content in the second dielectric layer is measured such that a refractive index of less than 2.0 results for the second dielectric layer.

2. The solar cell of claim 1,
wherein the second dielectric layer includes Silicon nitride with a layer thickness in a range of 50 nm to 200 nm.

3. The solar cell of claim 1,
wherein the solar cell is constructed as a PERC-solar cell.

4. A solar module, comprising:
a plurality of solar cells, each solar cell comprising:
a first dielectric layer on the shaded side of the solar cell; and
a second dielectric layer on the first dielectric layer;
wherein the second dielectric layer includes Hydrogen and the Hydrogen content in the second dielectric layer is measured such that a refractive index of less than 2.0 results for the second dielectric layer.

5. The solar module of claim 4, further comprising:
an encapsulation, which is configured such that the Hydrogen is embedded in the solar cell.

6. The solar module of claim 5,
wherein the encapsulation includes Ethyl vinyl acetate.

7. A process for manufacturing a solar cell, the process comprises:
deposition of a first dielectric layer on a shaded side of the solar cell by the addition of the gases Silane and Nitrogen dioxide;
subsequent deposition of a second dielectric layer on the first dielectric layer by the addition of the gases Silane and Ammonia, wherein the volume flow rate of the Ammonia is at least 15-folds greater than the volume flow rate of Silane.

8. The process of claim 7,
wherein the second dielectric layer is deposited as a Silicon nitride layer with a layer thickness in a range of 50 nm to 200 nm.

9. The process of claim 7,
wherein the solar cell is constructed as a PERC-solar cell.

10. The process of claim 7, further comprising:
heating the first dielectric layer and/or the second dielectric layer at 500° C. to 1000° C. for a time period of approximately 1 sec to approximately 10 sec.

11. The process of claim 7, further comprising:
wherein the Hydrogen content in the second dielectric layer is measured such that a refractive index of less than 2.0 results for the second dielectric layer.
